(19) United States
(12) Patent Application Publication
(10) Pub. No.: US 2009/0025774 A1
(43) Pub. Date: Jan. 29, 2009

(54) THERMOELECTRIC MEANS AND FABRIC-TYPE STRUCTURE INCORPORATING SUCH A MEANS

(75) Inventors: Marc Plissonnier, Eybens (FR); Yannick Breton, Lyon (FR); Isabelle Chartier, Grenoble (FR); Thierry Lanier, Vienne (FR); Christelle Navone, St Jean De Moirans (FR)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Commissariat A L'Energie Atomique

(21) Appl. No.: 12/177,347

(22) Filed: Jul. 22, 2008

(30) Foreign Application Priority Data
Jul. 23, 2007 (FR) 07/05331

(51) Int. Cl. H01L 35/16; H01L 35/28; H01L 35/14

(52) U.S. Cl. 136/224; 136/238; 136/239; 136/240

(57) ABSTRACT

The invention relates to a thermoelectric means (60) that can be woven or knitted, taking the form of an elongate body and having on its surface at least one converter for converting thermal energy into electrical energy. The invention also relates to a structure for converting a temperature difference over the thickness of the structure into electricity, which consists of an assembly formed by the interlacement of textile fibers (8), of said thermoelectric means (60) and of connection means (7).

### CROSS REFERENCE TO RELATED APPLICATIONS

This application claims priority from French patent application No. 0705331, filed Jul. 23, 2007.

### FIELD AND BACKGROUND OF THE INVENTION

The invention relates to the field of energy recovery systems applied to fabrics.

It relates to a structure of the fabric type for converting a temperature difference into electricity.

Textiles into which functions associated with electronic means are incorporated exist at the present time. These functions consist of the collection of information about the environment, thanks to sensors, such as temperature, atmospheric pressure or humidity sensors, or else detectors, or of the measurement of physiological parameters (such as heart beat, body temperature or blood pressure).

At the present time, these textiles incorporating electronic functions use, as energy source, lithium storage batteries which therefore have to be provided in the assembly incorporating this type of textile.

The main drawback of these textiles is therefore that they are not completely self-sufficient.

To overcome this drawback, it has already been proposed to incorporate thermoelectric converters, in the form of wires, into a textile structure.

As is known, a thermoelectric converter is able to convert thermal energy into electrical energy using the Seebeck effect. This principle is such that, in a closed circuit consisting of two conductors of different nature, a current flows when a temperature difference is maintained between the two junctions.

A thermoelectric converter consists of a plurality of pairs of two conductors of different nature. The two conductors of a pair are electrically connected in series and all the pairs of conductors are electrically connected in series and thermally connected in parallel. This arrangement makes it possible to optimize the thermal flux flowing through the converter and also its electrical resistance.

Throughout the description, the term “thermoelectric structure” should be understood to mean a structure for converting a temperature difference into electricity.

Thermoelectric structures in which two conductors of different nature are incorporated are already known. These conductors may be woven or knitted. By weaving or knitting it is possible to create connections between two conductors of different nature and therefore to produce pairs of conductors or thermocouples.

These conductors generally take the form of wires made of metals and/or alloys having sufficient ductility to allow them to be woven or knitted.

Certain structures include an epoxy resin substrate so as to ensure electrical isolation between the conductors.

In both cases, the thermocouples are electrically connected in series.

The use of weaving or knitting limits the type of materials that can be used, these having to be in the form of wires and to be sufficiently flexible.

In addition, some of these structures make it possible to convert only a temperature difference between two of their ends, considered in the plane of the structure, and not over their thickness. They therefore fail to exploit all the heat emitted by the human body when the structure is used to produce a garment.

Moreover, the use of wires made of metallic materials or alloys necessarily limits the thermoelectric performance of the structure obtained, these materials themselves being of low performance. In any case, the optimization of the thermoelectric performance of the structure is limited by the characteristics of the weaving looms or knitting machines, these imposing the diameter of the wires, the thickness of the structure and also the spacing of the wires or the size of the mesh cells.

Finally, when an insulating substrate is used, the structure obtained is relatively rigid. It therefore does not have the characteristics of a fabric and in particular cannot be used directly to produce a garment.

Other structures are also known which are not obtained by weaving or knitting.

Mention may particularly be made of thermoelectric energy generators that also use the Seebeck effect and consist of two plates or sheets between which a thermopile is placed. The plates or sheets may be rigid or flexible. The thermopile may be formed from a polyimide sheet on which thermocouples are connected in series, this sheet then being shaped so as to adopt a corrugated form.

Since this thermogenerator cannot be woven or knitted, it is necessarily added into the structure that incorporates electronic functions. When dealing with a garment, its design and its final appearance are modified insofar as the thickness of such a thermogenerator is relatively large, at around 3 mm.

### SUMMARY OF THE INVENTION

An object of the present invention is to alleviate the drawbacks presented by the solutions of the prior art.

In particular, the invention relates to a thermoelectric structure that can be used directly to produce a textile surface, advantageously a garment, and the thermoelectric performance of which is optimized.

One subject of the invention is therefore a structure for converting a temperature difference over the thickness of said structure, or else between its two faces, into electricity, said structure consisting of an assembly formed by the interlacement of textile fibers, of thermoelectric means, which are capable of converting thermal energy into electricity independently of their position in said structure, and of electrical connection means.

Preferably, the textile fibers are dielectric fibers.

Advantageously, the thermoelectric means are connected in parallel by said connection means.

The invention is based on the use of thermoelectric means which, before their assembly into the structure, exhibit a thermoelectric functionality. This enables the thermoelectric performance of the structure to be easily optimized according to the characteristics required by the electronic means, which need a power supply.

These thermoelectric means are therefore produced beforehand and then incorporated using weaving looms into the structure according to the invention.

Thus, the invention relates to a thermoelectric means that can be woven or knitted, taking the form of an elongate body and having on its surface at least one converter for converting thermal energy into electrical energy.

Preferably, said at least one converter comprises electrical conductors of different nature so as to define at least two electrical junctions that are located at opposed ends of said conductors and electrically connect said conductors in series, said at least two junctions being placed on either side of said body along the direction in which said body extends.

Moreover, the body may include a flexible thermally insulating support to which said at least one converter is fixed and folded thereon.

This support may take the form of a tape of approximately rectangular cross section, said converter being approximately in the form a U.

In one advantageous embodiment, said at least one converter comprises a plurality of thermocouples placed electrically in series and thermally in parallel, these thermocouples being placed on an electrically insulating substrate, which is folded transversely to the thermocouples.

The substrate may take the form of a polymer sheet, advantageously a polyimide, polyethylene, polyamide or polyester sheet.

In a preferred embodiment, the thermocouples are in the form of thin films of thermoelectric materials such as Bi, Sb, Bi₂Te₃, alloys based on Bi and Te, on Sb and Te or else on Bi and Se, or else Si/SiGe superlattices.

The support may take the form of a tape made of a material chosen from textile fibers and/or polymer materials, such as polyimide, polyethylene, polyamide or polyester.

The converter may have electrical junctions on each of the two faces of the substrate.

### BRIEF DESCRIPTION OF THE DRAWINGS

The invention will be better understood and other objects, advantages and features thereof will become more clearly apparent on reading the following description, given in conjunction with the appended drawings in which:

FIG. 1 shows schematically a thermoelectric converter illustrating the Seebeck effect;

FIG. 2 shows one step in the manufacture of a thermoelectric means according to the invention;

FIG. 3 shows another step in the manufacture of a thermoelectric means according to the invention;

FIG. 4 shows one embodiment of a thermoelectric means according to the invention;

FIG. 5 illustrates an example of a structure in accordance with the invention; and

FIG. 6 is an electrical circuit modeling the structure illustrated in FIG. 5.

The elements common to the various figures will be denoted by the same references.

### MORE DETAILED DESCRIPTION

Referring firstly to FIG. 1, this illustrates a thermoelectric converter consisting here of three pairs 1 of electrically connected conductors. Each pair comprises two electrical conductors 10, 11 of different nature.

As illustrated in FIG. 1, the two conductors 10, 11 of a given pair 1 are electrically connected in series, the pairs 1 also being electrically connected in series. The current flowing within the converter is indicated schematically by I.

Finally, the pairs of conductors are thermally connected in parallel. In the example illustrated in FIG. 1, a temperature difference exists between the hot face 20 and the cold face 21 of the thermoelectric converter, through which a heat flux illustrated by the arrow F flows.

The efficiency of such a converter is directly proportional to the temperature difference applied between the two faces of the converter.

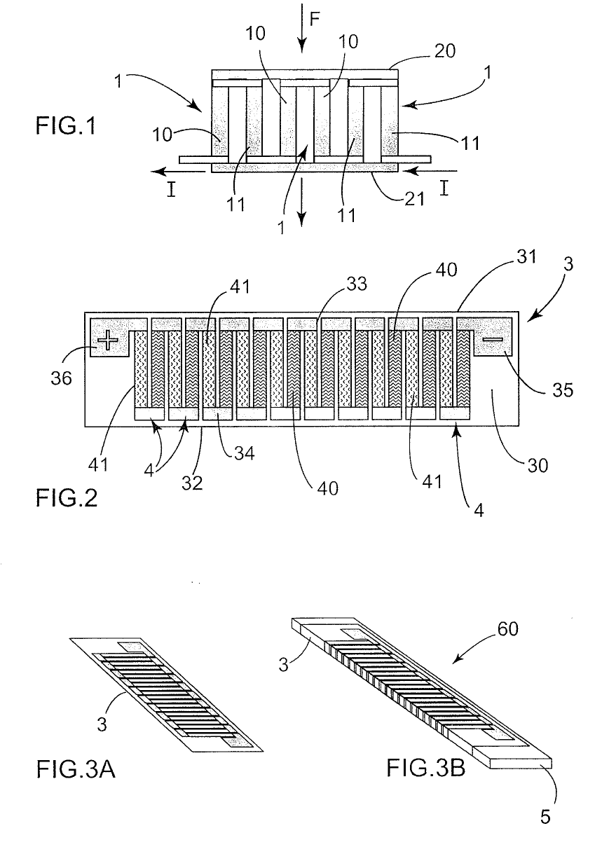

Referring now to FIG. 2, this illustrates the first step in the manufacture of a thermoelectric means 3 according to the invention.

FIG. 2 illustrates a flexible substrate 30, which is approximately plane and elongate, on which the pairs 4 of conductors or thermocouples have been deposited, each consisting of two conductors 40, 41 of different nature. They extend approximately perpendicular to the longitudinal direction of the substrate.

The conductors 40, 41 of each pair, and also all the pairs 4, are electrically connected in series by means of junctions 33, 34 located along each longitudinal face 31, 32 of the substrate. When a temperature difference is applied between the two faces 31, 32, an electrical current is generated between the two terminals 35, 36.

The conductors may be produced using mechanical masks or the technique of photolithography and etching.

Moreover, the pairs of conductors produced in the form of thin films are thermally connected in parallel.

If a heat flux flows through the thermoelectric means from the face 31 to the face 32, in such a way that a temperature difference appears between its two faces, the face 31 will be called the hot face and the face 32 the cold face. Likewise, the junctions 33 will be called hot junctions and the junctions 34 will be called cold junctions.

In general, the Seebeck voltage U_{S} of the thermoelectric means 3 depends on the number of thermocouples connected and on the temperature difference between each of the faces 31, 32 of the thermoelectric means or between the junctions 33, 34 at each end of the conductors:

U_{S}=nSₚₐᵢᵣΔT

where
U_{S} is the Seebeck voltage of the device,
n is the number of thermocouples connected,
Sₚₐᵢᵣ is the coefficient of the chosen thermoelectric couple and
ΔT is the temperature difference between the junctions 33, 34 at each end of the pairs 4 of conductors.

Thus, for a given temperature difference, only the number and the nature of the thermocouples connected will enable the desired voltage to be defined.

Finally, by optimizing the cross section/length ratio of the conductors it is possible to firstly optimize their resistance.

FIG. 3 shows, in perspective, the thermogenerator sheet illustrated in FIG. 2 (FIG. 3A) and this same sheet 3, folded around a support 5 and bonded thereto, so as to obtain a thermoelectric means 60 according to the invention.

In the example illustrated in FIG. 3, the support 5 takes the form of a weavable tape or a fibril. This support could likewise take the form of a thread. It is also obvious that the support could be omitted. In this case, it is sufficient for the substrate to be rigid enough for the U-shaped structure to be self-supporting.

The term “fibril” is well known in the textile field and may be defined as a continuous narrow strip, of small thickness compared with its width, obtained by slitting a film, or by direct spinning.

In all cases, the support is insulating and flexible and is of elongate shape.

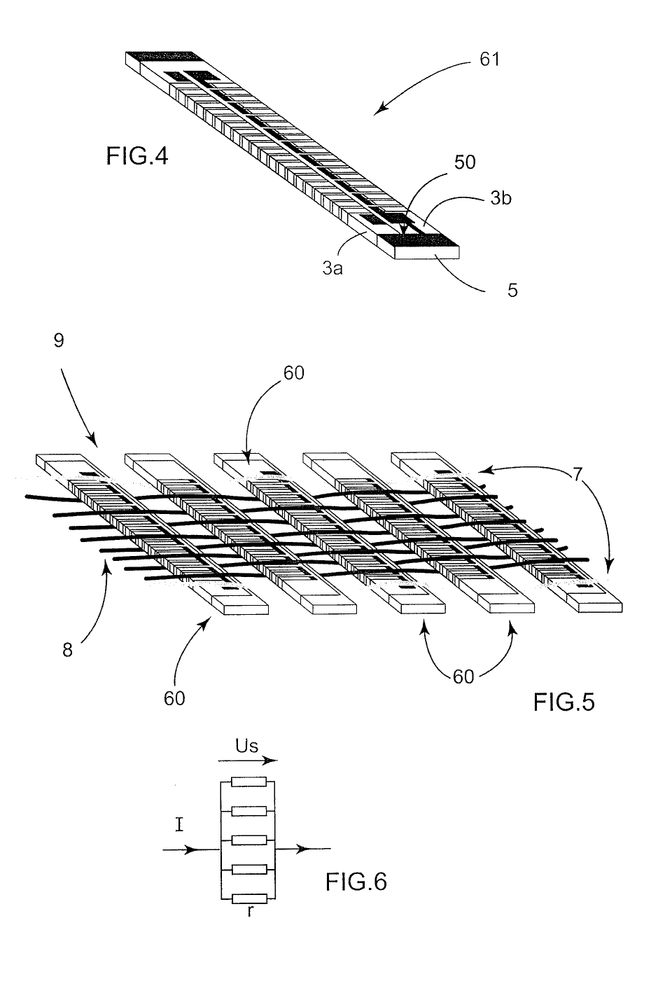

FIG. 4 shows one embodiment of a thermoelectric means according to the invention, in which two thermogenerator sheets 3 are folded over and fixed to one and the same insulating support 5.

In practice, the thermoelectric means 61 illustrated in FIG. 4 can be produced from the means 60 illustrated in FIG. 3.

To do this, all that is required is to fold another sheet 3 around the support 5 and to bond it thereto, symmetrically about a longitudinal mid-axis of the support 5 relative to the first thermogenerator sheet.

The thermoelectric means 61 thus comprises two thermogenerator sheets 3a and 3b placed head to tail or symmetrically relative to a longitudinal mid-axis of the support 5, a deposit of metal 50 possibly being provided on the support 5 so as to provide an electrical connection between the two sheets 3a and 3b.

Another way of optimizing the surface consists in superposing on one side several electrical means connected in series or in parallel, the insulation between them being provided by the substrate.

Finally, it is also conceivable to produce the thermoelectric means on each of the faces of the substrate.

With this embodiment, the useful surface is optimized by increasing the number of pairs of conductors.

As regards firstly the thermoelectric materials that can be used to produce the conductors, it should be recalled that the theoretical efficiency of a thermoelectric generator or of a thermoelectric cooler depends directly on a dimensionless coefficient ZT. This coefficient, called the factor of merit, is equal to S²σT/K where S is the Seebeck coefficient, σ is the electrical conductivity, K is the thermal conductivity and T is the absolute temperature.

A high efficiency requires materials with a high ZT coefficient and therefore a high electrical conductivity so as to reduce the Joule heating to a minimum when the electrical current is flowing through the material, a low thermal conductivity, so as to reduce the thermal bridge phenomenon between the hot part and the cold part of the generator or of the cooler, and a high Seebeck coefficient, for optimum conversion of the heat into an electrical current.

The higher the factor of merit, the higher the performance of the device. Thus, the choice of materials deposited, together with the structure chosen (thin films or superlattice), will define the factor of merit ZT and therefore the electrical performance.

At the present time, the best thermoelectric materials have a ZT value of about 1 for a given temperature range.

As various studies indicate, the nature of the thermoelectric materials that can be deposited on a flexible substrate is extremely broad: metals and metal alloys, but also thermoelectric materials having the best performance such as Bi, Sb, Bi₂Te₃ or even Si/SiGe superlattices. The choice of materials will be made according to the cost, the required toxicological criterion and the desired electrical performance.

The invention allows the use of any type of thermoelectric material, such as alloys of the BiₓTe_{y}, SbₓTe_{y} and BiₓSe_{y} type, these materials having the best thermoelectric performance at 300 K, or SiGe, a biocompatible material, or rare-earth skutterudites.

It is also possible to envision depositing superlattices, which enable the power factor S²σ to be increased, while greatly lowering the contribution of the phonons in the crystal lattice by quantum size effects of the superlattices. Thus, it is possible to envision Bi₂Te₃/Sb₂Se₃ superlattices (the factor of merit of which is about 3), PbTe/PbTeSe superlattices (“quantum dot”, the factor of merit of which is about 2), Si/Ge superlattices (the factor of merit of which is about 3) or n-Si/SiGe and p-B₄C/B₉C superlattices.

Conventionally, the term “superlattice” covers a stack of very thin successive layers (the thickness of which is less than 10 nm) and the term “quantum dot” denotes an inclusion of nanoscale aggregates in another material.

Semiconductor nanoparticles (nanoinclusions) having a band structure similar to that of the thermoelectric material may be incorporated into the deposit. These have the effect of increasing the factor of merit ZT and therefore the performance of the thermogenerator. Thus, for a Ge or SiGe deposit, Si or SiGe inclusions may be incorporated (or, conversely, Ge nanoparticles may be incorporated into a silicon matrix). The matrix and the inclusion material may be n-doped or p-doped. In general, the concentration of dopants will be optimized for the various combinations of materials envisioned.

It is also possible to produce combinations with “host” materials of the SiGe, PbTe or Bi₂Te₃ type incorporating PbSe, PbSeTe or Sb₂Te₃ inclusions (or vice versa). Other conceivable materials are PbSn or PbTeSeSn alloys. Materials of group III-V may also be used, as may HgCdTe, Bi or BiSb systems.

The thin films will be deposited by deposition techniques such as sputtering, evaporation or PECVD, or else by printing (inkjet, photogravure, flexography) or screen printing techniques.

As indicated with reference to FIG. 2, the substrate 30 is approximately plane and flexible. It is also preferable for it to have a small thickness and to be of low thermal and electrical conductivity.

Depending on the deposition techniques chosen and on the intended application, high thermal and chemical stability may also be necessary.

The substrate best suited is made of a polymer, for example a sheet of polyimide (sold for example under the brand name Kapton®), since this material has a unique combination of all of the necessary properties for a wide choice of applications. However, other materials, such as polyester, polyethylene, polyimide, polystyrene, polypropylene or polycarbonate, may be envisioned as substrate, but also paper.

The material used to produce the electrical junctions between the conductors has a high electrical conductivity so as to minimize the contact resistances and also a high thermal conductivity, to ensure good thermal coupling.

As regards the support 5 for the thermogenerator sheet, the choice of its thickness and of its nature will ensure the thermal gradient between the two faces of the thermoelectric means obtained.

The support is preferably a fibril or tape of rectangular cross section. The width and the thickness of the fibril may vary from around 100 microns to 1 millimeter. The choice of thickness will depend on the desired temperature difference, knowing that ΔT=Φ(e/λ) where Φ is the heat flux flowing through the textile, e is the thickness of the fibril and λ is the thermal conductivity of the fibril.

The length of the tape or of the thread will be defined by the desired dimension of the textile. The entire length of the thread/fibril may be used to assemble a large number of thermoelements, and consequently to allow the desired voltage to be obtained.

It is also possible to envision a stack of a few thermogenerator sheets as illustrated in FIG. 4 so as to increase the number of thermoelements in series and therefore the voltage, and consequently to increase the useful power density. The fact that the substrate used for depositing the thermoelectric materials is very thin makes it possible to modify the thickness of the fibril, and therefore the size of the thermoelectric means according to the invention, only slightly.

The description now refers to FIG. 5, which illustrates an example of a thermoelectric structure according to the invention.

This structure is produced from thermoelectric means, such as the means 60 illustrated in FIG. 3B, from conducting wires 7 and from insulating threads 8. Thus, this structure consists of an assembly formed by interlacing these various elements.

In practice, this assembly is produced directly by means of a loom or knitting machine. All the constituent elements of the structure are thus woven or knitted at the same time.

The conducting wires 7, typically metal wires, are used to connect the thermoelectric means 60 in parallel. To do this, the contacts between the conducting wires 7 and the thermoelectric means 60 are made alternately between the two faces of the structure 9.

The Seebeck voltage of the structure according to the invention is fixed by the number of thermocouples linked in series on a thermoelectric means 60. In addition, the electrical resistance of the structure according to the invention may be optimized by placing the thermoelectric means 60 in parallel.

If the desired application requires a current I, the number x of thermoelectric means, having a resistance r, connected in parallel, will be:

x=rI/U_{S}

where U_{S} is the Seebeck voltage of the structure.

FIG. 6 shows the electrical circuit corresponding to the structure according to FIG. 5. Thus, each thermoelectric means 60 has a resistance r. They are all electrically connected in parallel, and here 5 U_{S}=rI.

It is the textile threads 8 and the connection wires 7 that provide the structure according to the invention with mechanical integrity. The threads 8 also provide the insulation between the thermoelectric means 60.

An exemplary embodiment of a thermoelectric structure according to the invention is given below.

This uses thermoelectric alloys based on n- or p-type Bi₂Te₃ to produce thermocouples on a substrate. The thermoelectric characteristics of this pair are: λ=1.5 W/mK, ρ=2.5 mΩcm and S=400 μmV/K. Thus, for a fibril 25 μm in thickness, 1 mm in width and 1 m in length, it is possible to connect 1000 thermoelements of 500 μm width spaced apart by 500 μm, i.e. 500 thermocouples. The stack of four thermogenerator sheets will enable a voltage of 1 V to be obtained for a temperature difference ΔT of 1.3° C.

To obtain a current of 10 mA, it is necessary to place 370 fibrils in parallel. This will be accomplished using a loom or knitting machine (for example of the RACHEL TRAMER mode).

It will be understood that the advantages offered by the invention are numerous.

First of all, the invention makes it possible to produce thermoelectric means that can convert thermal energy into electricity, even before they are assembled into the final structure.

Moreover, thanks to the invention, a thermoelectric structure may be obtained by simultaneously weaving or knitting the textile fibers, the thermoelectric means and the connecting fibers.

The structures obtained make it possible to exploit the temperature difference between its two faces. Thus, the active surface of the structure obtained has an area of the same order of magnitude as that of the surface of the garment produced with it. Consequently, the electrical energy delivered may be significant, it being possible for all the heat emitted by the human body to be used.

The electrical connection is made in a simple manner, by means of conducting wires. This enables the thermoelectric characteristics of the structure to be optimized depending on the application.

Moreover, the overall efficiency of the structure according to the invention may be increased by using very high-performance thermoelectric materials.

Finally, the structure according to the invention retains a textile aspect—being pliant, breathable, conformable (moldable, injectable) and able to be made up into clothing, and its thickness may be small as it will be compensated for by the large area and an appropriate choice of the electrical materials.

This structure may also be used as a covering for any device hotter than the ambient air (boiler, pipework, etc.) so as to recover the energy.

Said structure may also be combined with another, curable material (for example a resin) so as to obtain a composite having thermoelectric properties, which can be easily adapted to the desired shape (for example an airplane wing).

The reference signs mentioned after the technical features appearing in the claims have the sole purpose of making it easier to understand these claims but do not limit the scope thereof.

1. Thermoelectric means that can be woven or knitted, taking the form of an elongate body and having on at least one of its surfaces at least one converter for converting thermal energy into electrical energy, wherein said at least one converter is folded so as to form a U-shaped structure.

2. Thermoelectric means according to claim 1, in which said at least one converter comprises electrical conductors of different nature so as to define at least two electrical junctions that are located at opposed ends of said conductors and electrically connect said conductors in series, said at least two junctions being placed on either side of said body along the direction in which said body extends.

3. Thermoelectric means according to claim 1, the body comprising a flexible thermally insulating support in which said at least one converter is fixed and folded thereon.

4. Thermoelectric means according to claim 3, in which said support takes the form of a tape of approximately rectangular cross section and said converter is approximately in the form of a U.

5. Thermoelectric means according to claim 1, in which said at least one converter comprises a plurality of thermocouples placed electrically in series and thermally in parallel, said thermocouples being placed on an electrically insulating substrate, which is folded transversely to the thermocouples.

6. Thermoelectric means according to claim 5, in which said substrate is a polymer sheet, advantageously a polyimide, polyethylene, polyamide or polyester sheet.

7. Thermoelectric means according to claim 5, in which the thermocouples are in the form of thin films of thermoelectric materials selected from the group consisting of Bi, Sb, Bi₂Te₃, alloys based on Bi and Te, on Sb and Te or else on Bi and Se, or else Si/SiGe superlattices.

8. Thermoelectric means according to claim 5, in which the support takes the form of a tape made of a material chosen from textile fibers and/or polymer materials, advantageously polyimide, polyethylene, polyamide or polyester.

9. Thermoelectric means according to claim 5, in which the converter has junctions on each of the two faces of the substrate.

10. A structure for converting a temperature difference over the thickness of said structure into electricity, which consists of an assembly formed by the interlacement of textile fibers, of thermoelectric means according to claim 1, which are capable of converting thermal energy into electricity independently of their position in said structure, and of electrical connection means.

11. A structure according to claim 10, in which the textile fibers are dielectric fibers.

12. A structure according to claim 10, in which said thermoelectric means are connected in parallel by said connection means.
